(19) United States
(12) Patent Application Publication
(10) Pub. No.: US 2009/0140313 A1
(43) Pub. Date: Jun. 4, 2009

(54) Nonvolatile memory devices and methods of forming the same

(75) Inventor: Joon-Yong Joo, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/292,732

(22) Filed: Nov. 25, 2008

(30) Foreign Application Priority Data
Nov. 30, 2007 (KR) 10-2007-0123590

(51) Int. Cl. H01L 27/115; H01L 21/8247

(52) U.S. Cl. 257/314; 438/258; 257/E27.103; 257/E21.68; 257/E21.628; 257/E21.626; 257/E21.622

(57) ABSTRACT

A method of forming nonvolatile memory devices according to example embodiments of the present invention includes forming a device isolation layer defining active regions in a semiconductor substrate; forming a plurality of transistors on the active regions, the plurality of transistors comprising a pair of adjacent string selection transistors, a pair of adjacent ground selection transistors, and a plurality of memory cell transistors connected in series between the string selection transistors and ground selection transistors; forming a common source line using SEG between a pair of adjacent ground selection transistors so that the common source line has a top surface lower than a top surface of the pair of adjacent ground selection transistors.

### PRIORITY STATEMENT

This application claims priority under 35 U.S.C. §119 to Korean Patent Application No. 10-2007-0123590, filed on Nov. 30, 2007, in the Korean Intellectual Property Office (KIPO), the entire contents of which is incorporated herein by reference.

### BACKGROUND

1. Field

Example embodiments relate to semiconductor memory devices and methods of fabricating the same, and for example, to a common source line of nonvolatile memory devices and methods of fabricating the same.

2. Description of the Related Art

Semiconductor memory devices may store data and read the data when necessary. Semiconductor memory devices can be classified as random access memory (RAM) or read only memory (ROM). A RAM is a volatile memory device that loses its stored data when its power supply is interrupted. A ROM is a nonvolatile memory device that can maintain stored data even when its power supply is interrupted.

Examples of RAMs include a dynamic RAM (DRAM) and a static RAM (SRAM). Examples of ROMs include a programmable ROM (PROM), an erasable programmable ROM (EPROM), an electrically EPROM (EEPROM), and a flash memory. Flash memory devices are classified into a NAND-type flash memory device and a NOR-type flash memory device. A NAND flash memory device has very high integration as compared with a NOR flash memory device

FIG. 1 is a cross-sectional view illustrating a conventional NAND flash memory device.

Referring to FIG.1, a conventional nonvolatile memory device is created by forming, on an active region in a semiconductor substrate 1, a plurality of memory cell transistors (MT1-MTn), a string selection transistor (SST), and a ground selection transistor (GST). The memory cell transistors (MT1-MTn) are connected to each other in series between the string selection transistor (SST) and the ground selection transistor (GST) to form a string. The drain 12 of a string selection transistor (SST) is connected to a bit line (BL) through a bit line contact plug (BC). The source 14 of a ground selection transistor (GST) is connected to a common source line (CSL). Each of the memory cell transistors (MT1-MTn) may have a gate structure including a tunnel oxide layer 4, a charge storage layer 6, a gate dielectric interlayer 8 and a control gate electrode 10 that are sequentially stacked on the semiconductor substrate 1. The charge storage layer 6 may be a floating gate or a charge trap layer. Each of the memory cell transistors (MT1-MTn) have a source and drain 16 that may be self aligned with the gate structure.

The manufacture of a conventional nonvolatile memory device may be complicated by the conductive interconnects within the device. The interconnects may connect portions of a single component (e.g., a transistor), one component to another component, multiple components together, one area of the memory device to another, and/or any other connection necessary to implement the operation of the memory device.

Most conductive layers may not contact each other and, in many cases, should not be in continuous proximity such that they are electrically and/or magnetically coupled to each other. However, many conductive layers must unavoidably cross each other. In the conventional art, isolation of the conductive layers is accomplished by raising the conductive layers vertically with respect to each other and forming an insulating interlayer in between.

A conventional interconnect manufacturing process typically proceeds as follows: after transistors are created on a substrate (e.g. silicon), an insulating layer is formed over the transistors; conductive connectors, called contact plugs, are created so that they extend through the insulating layer to the transistors, and; conductive layers are formed over the insulation layer, so that they are in contact with the plugs (although in some processes the plugs and metal layer may be created together). This creates a continuous pathway from the transistor to the metal layer while isolating it from other conductive layers. A simple example of the resulting structure can be seen by referring to the bit line (BL) and bit line contact plug (BC) in FIG. 1. Note that the bit line (BL) is raised such that it does not contact any of the underlying transistors or the common source line (CSL) as it extends across them.

A plurality of processes are typically required to form conventional contact plugs, which are generally formed of a conductive metal (e.g. tungsten). The plurality of processes may include: creating a contact hole photoresist pattern over a first insulating interlayer; etching an opening into the first insulating interlayer to form contact holes; stripping the photoresist pattern; cleaning the exposed contact areas inside the contact holes (e.g. removing oxide); depositing an adhesion and/or barrier metal layer onto the contact areas, depositing a conductive metal into the contact holes to fill them, and; annealing the deposited metal contact plugs. Depending on the device or process, additional steps may also be required. For example, if the metal lines will be made of a different metal than the plugs, the plugs may need to be planarized and additional adhesion and/or barrier layers may be required.

An additional plurality of processes are typically required to form the raised metal lines: a metal layer may be deposited over the first insulating interlayer and contact plugs; a resist pattern may be formed over the metal layer; the metal layer may be etched to form metal lines contacting one or more contact plugs; the photoresist pattern may be stripped; and a second insulating interlayer may be formed over the metal lines to isolate the metal lines from the next metal layer. Referring to FIG. 1, the second insulating interlayer may, for example, insulate the common source line (CSL), extending into FIG. 1 (not shown), from the bit line (BL), extending across FIG. 1, while the first insulating layer insulates both of these conductive lines from the underlying transistors (SST, GST, MT1-MTn). Depending on the device or process, additional steps may also be required. For example, the metal layer may need to be planarized prior to patterning and/or additional conductive layers may be deposited (e.g. adhesion and/or barrier).

In using these processes, a number of problems may arise, especially in a highly integrated semiconductor device. For instance, misalignment of a contact hole may occur and if a common source line (CSL) is not formed over the contact hole, it may not be electrically connected to a ground selection transistor (GST). As another example, when a contact hole for a common source line (CSL) is under etched (the material in the contact hole is not completely removed), it may not be electrically connected to a source 14 of a ground selection transistor (GST), and if it is over etched (material from the source is removed), a leakage current may be generated between a source 14 and a semiconductor substrate 1. Finally, an insulating interlayer disposed between transistors (SST, GST, MT1-MTn) formed on a substrate and a bit line (BL) may not be highly formed enough to isolate a common source line (CSL) from a bit line (BL).

### SUMMARY

Example embodiments relate to nonvolatile memory devices and methods of fabricating them. Example embodiments may eliminate the problems that arose in conventional fabrication of a common source line (CSL), such as misalignment of the photoresist pattern (PR), over and under etch of the common source line (CSL), and/or failure to isolate the common source line (CSL) from a bit line (BL). Example embodiments may also eliminate the need for a plurality of conventional manufacturing steps.

According to example embodiments, a method of fabricating a nonvolatile memory device is described, which may include: forming a device isolation layer that defines active regions in a semiconductor substrate; forming a plurality of transistors on the active regions, where the plurality of transistors may include a pair of adjacent string selection transistors, a pair of adjacent ground selection transistors, and a plurality of memory cell transistors connected in series between the string selection transistors and ground selection transistors, and; forming a common source line using selective epitaxial growth (SEG) between a pair of adjacent ground selection transistors so that the common source line may have a top surface lower than a top surface of the pair of adjacent ground selection transistors.

According to example embodiments, a nonvolatile memory device is described. The device may include: a device isolation layer defining active regions in a semiconductor substrate; a pair of adjacent string selection transistors on the active regions; a pair of adjacent ground selection transistors on the active regions; a plurality of memory cell transistors connected in series between the string selection transistors and the ground selection transistors on the active region; and a common source line including a silicon layer and a metal silicide layer on the silicon layer formed on the active region between the pair of adjacent ground selection transistors using selective epitaxial growth (SEG), wherein the common source line may have a top surface lower than top surfaces of the transistors.

### BRIEF DESCRIPTION OF THE DRAWINGS

Example embodiments will be more clearly understood from the following brief description taken in conjunction with the accompanying drawings. FIGS. 1-10 represent non-limiting, example embodiments as described herein.

FIG. 1 is a cross-sectional view of a conventional NAND flash memory device.

FIG. 2 is a top plan view of a nonvolatile memory device in accordance with example embodiments.

FIG. 3 is an example perspective view of the nonvolatile memory device shown in FIG. 2.

FIG. 4 is an example cross-sectional view taken along the line A-A′ of FIGS. 2 and 3.

FIGS. 5A through 5E are example cross-sectional views taken along the line A-A′ of FIGS. 2 and 3, the cross-sectional views illustrating a method of forming a nonvolatile memory device in accordance with example embodiments.

FIG. 6 is a top plan view of a nonvolatile memory device in accordance with example embodiments.

FIG. 7 is an example perspective view of a nonvolatile memory device shown in FIG. 6.

FIG. 8 is an example cross-sectional view taken along the line B-B′ of FIGS. 6 and 7.

FIG. 9 is a top plan view illustrating a method of forming a nonvolatile memory device in accordance with example embodiments.

FIGS. 10A through 10C are example cross-sectional views taken along the line B-B′ of FIGS. 6,7 and 9, the cross-sectional views illustrating a method of forming a nonvolatile memory device in accordance with example embodiments.

FIG. 11 is a cross-sectional view of a nonvolatile memory device in accordance with example embodiments.

FIG. 12 is an example cross-sectional view taken along the line B-B′ of FIGS. 6 and 7, the cross-sectional view showing a nonvolatile memory device.

FIGS. 13A through 13D are cross-sectional views taken along the line B-B′ of FIGS. 6, 7 and 9, the cross-sectional views illustrating a method of forming a nonvolatile memory device in accordance with example embodiments.

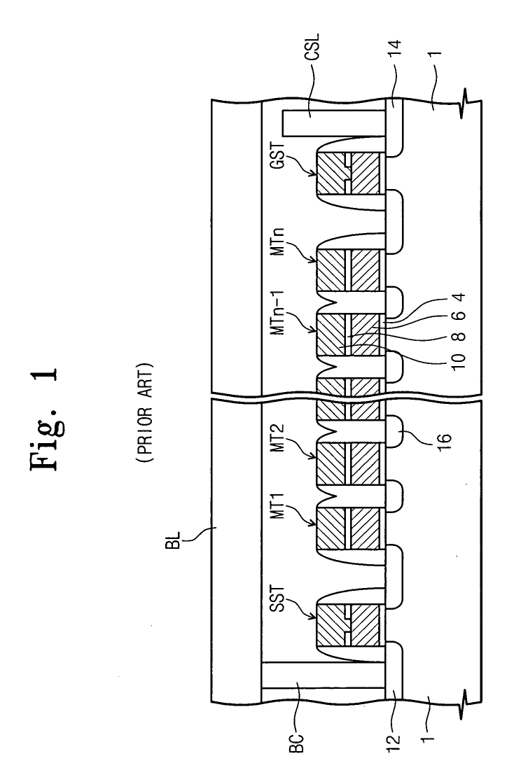

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

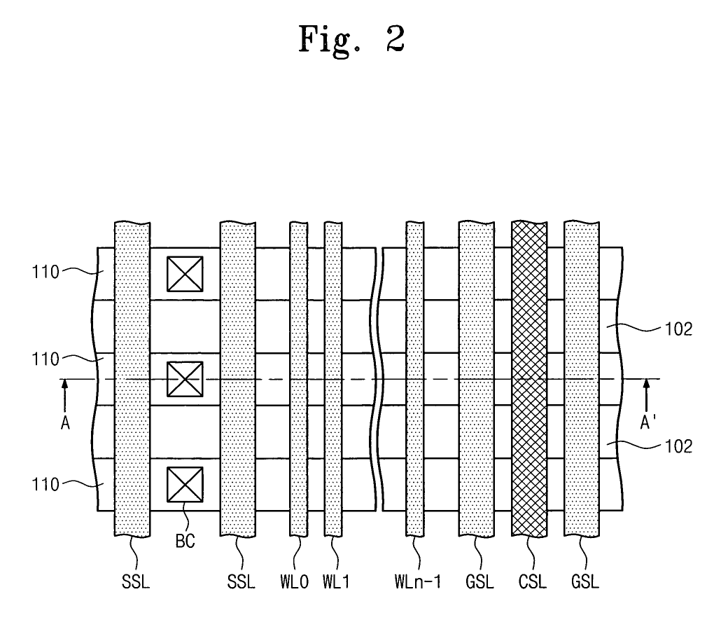

Example embodiments of a nonvolatile memory device will be described with reference to FIGS. 2 through 4. In example embodiments, active regions 110 in a semiconductor substrate 100, that may be a silicon substrate, may be formed parallel to each other by forming device isolation layers 102. A plurality of transistors (SST, GST, MT0-MTn-1) may be formed on active regions 110. This transistor plurality may itself be composed of a plurality of memory cell transistors (MT0-MTn-1) that may be formed between a pair of adjacent ground selection transistors (GST) and a pair of adjacent string selection transistors (SST). The plurality of memory cell transistors (MT0-MTn-1) may form a string. A string selection line (SSL) connected to the string selection transistor (SST) may extend in a direction crossing the active region 110. A bit line (BL) may be connected to an active region disposed between a pair of adjacent string selection transistors (SST), through a bit line contact (BC), and the bit line (BL) may extend onto the active region 110. A common source line (CSL) may be formed on an active region disposed between a pair of adjacent ground selection transistors (GST). The common source lines (CSL) may cross the active region 110 to extend onto the device isolation layer 102 and may be connected to each other. A top surface of the common source line (CSL) may be lower than top surfaces of the transistors (SST, GST, MT0-MTn-1).

Each of the transistors (SST, GST, MT0-MTn-1) may have a gate structure 120 including a tunnel insulating layer 121 on the semiconductor substrate 100, a charge storage layer 123 on the tunnel insulating layer 121, a blocking insulating layer 125 on the charge storage layer, a control gate layer 127 connected to the selection lines (SSL, GSL) or word lines (WL0-WLn-1), and a capping layer 129 on the control gate layer 127. The control gate layer 127 may include a polysilicon layer and a metal silicide layer on the polysilicon layer. A sidewall spacer 133 may be provided on the side surface of the gate structure 120. The charge storage layer 123 and control gate layer 127 of the selection transistors (SST, GST) may be electrically connected to each other. The bit line (BL) and the transistors (SST, GST, MT0-MTn-1) may be electrically disconnected from each other by an etch stop layer 141 and an insulating interlayer 143.

According to example embodiments, the common source line (CSL) may include a silicon layer 134a formed by epitaxial growth and a metal silicide layer 134b on the silicon layer 134a. Accordingly, a plurality of process steps may be eliminated (e.g. steps related to the formation of a contact plug).

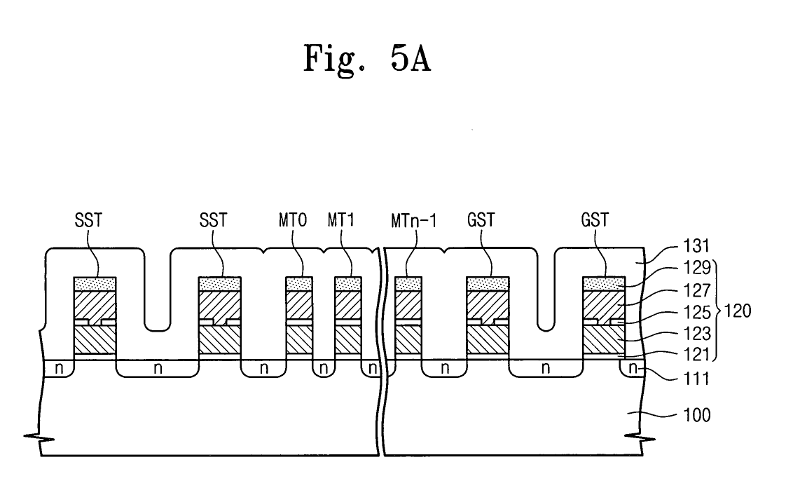

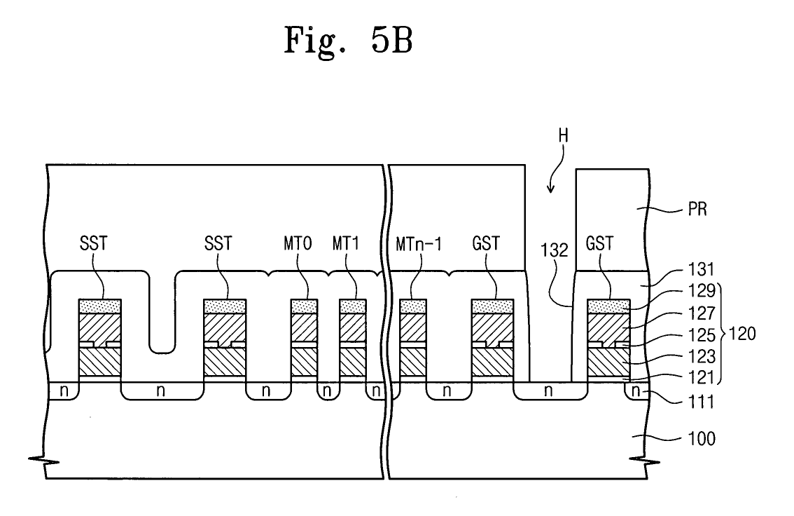

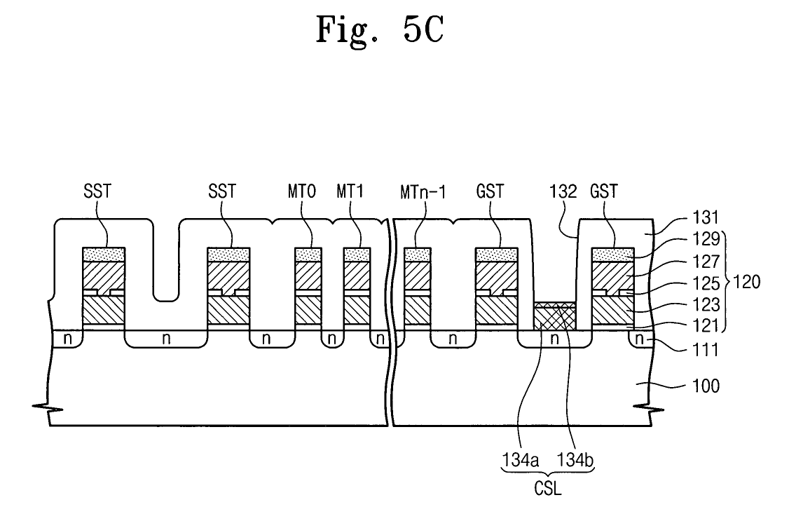

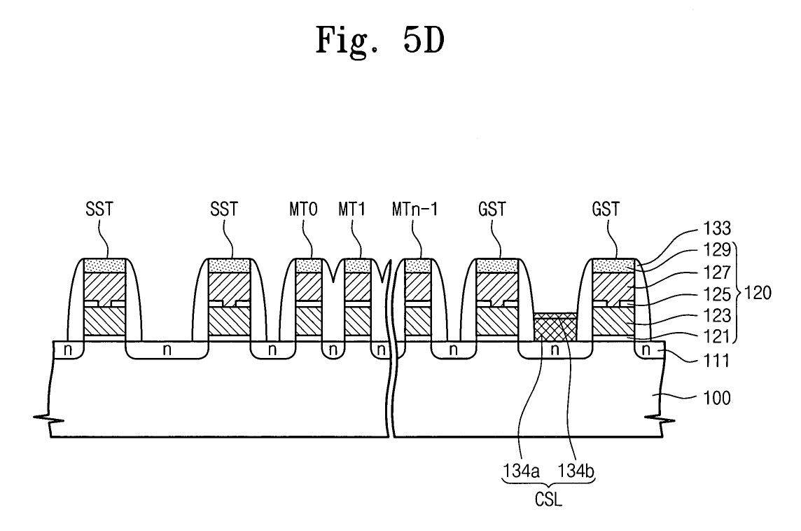

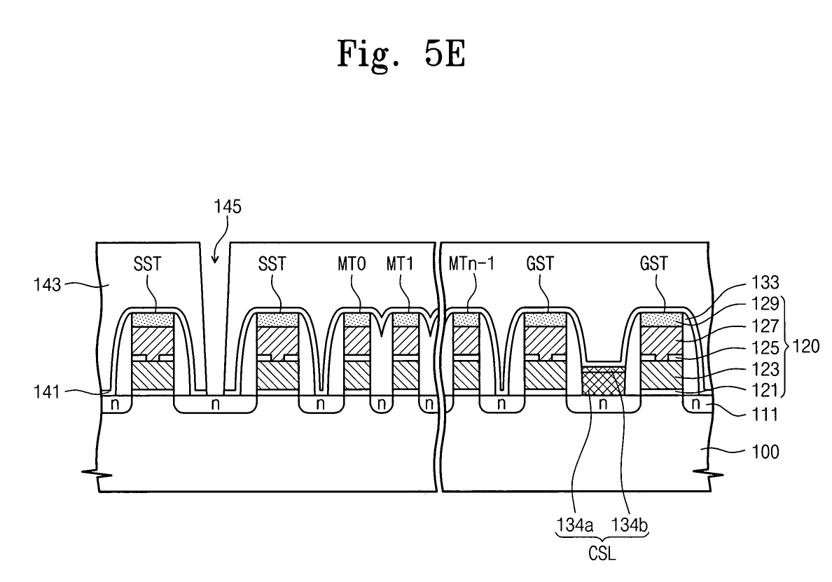

Referring to FIGS. 5A through 5E, a method of forming a nonvolatile memory device according to example embodiments will be described.

Referring to FIGS. 2 and 5A, a device isolation layer 102 may be formed inside a semiconductor substrate 100. The device isolation layer 102 may define the active regions 110 for transistors (SST, GST, MT0-MTn-1).

A gate structure 120, including a capping layer 129, a control gate layer 127, a blocking insulating layer 125, a charge storage layer 123 and a tunnel insulating layer 121 may be formed. A tunnel insulating layer 121 may be formed on the active regions 110. The tunnel insulating layer may include, for example, a silicon oxide layer. A charge storage layer 123 may be formed on the tunnel insulating layer 121. The charge storage layer 123 may be a floating gate including polysilicon. The charge storage layer 123 may include a dot layer or a charge trap layer. The dot layer may include a conductor of a dot shape or an insulating layer including an insulator. The charge trap layer may be an insulating layer (e.g., a silicon nitride layer) including a site in which charges can be trapped. A blocking insulating layer 125 may be formed on the charge storage layer 123. The blocking insulating layer may include, for example, ONO (oxide/nitride/oxide). A control gate layer 127 may be formed on the blocking insulating layer 125. The control gate layer 127 may include, for example, polysilicon. A metal silicide layer may be formed on the polysilicon layer. The metal silicide layer may be, for example, a tungsten silicide layer, a cobalt silicide layer or a nickel silicide layer. A portion of the blocking insulating layer 125 of the selection transistors (SST, GST) may be etched to electrically connect the control gate layer 127 to the charge storage layer 123. This is because the selection transistors (SST, GST) may act as a conventional MOS transistor. A capping layer 129 may be formed on the control gate layer 127. The capping layer 129 may include, for example, a silicon nitride layer. The capping layer 129, the control gate layer 127, the blocking insulating layer 125, the charge storage layer 123 and the tunnel insulating layer 121 may be patterned in order.

Impurities may be implanted into active regions between the gate structures 120 to form sources/drains of the transistors (SST, GST, MT0-MTn-1). A spacer insulating layer 131 for a sidewall spacer may be deposited on the gate structure 120. The spacer insulating layer may be, for example, a silicon oxide layer, a silicon nitride layer or a combination of a silicon oxide layer and a silicon nitride layer.

Referring to FIG. 5B, a photoresist pattern (PR) may be formed on the spacer insulating layer 131. The photoresist pattern (PR) may include an opening (H) that corresponds to the common source line (CSL). The spacer insulating layer 131 may be etched to form a common source trench 132 exposing active regions and device isolation layers of the opening (H) that corresponds to the common source line (CSL).

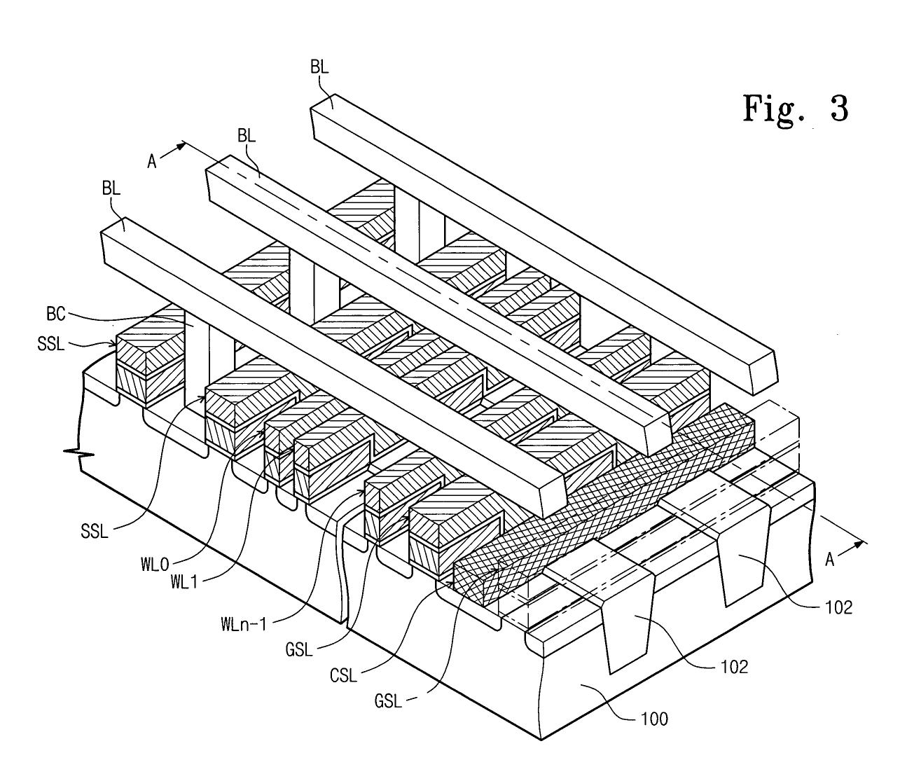

Referring to FIG. 5C, the photoresist pattern (PR) may be removed. A silicon layer may be grown from top surfaces of the active regions exposed by the common source trench 132. The silicon layer may be grown using selective epitaxial growth (SEG). For example, a silicon layer may be grown only on the active regions 110 which correspond to the common source line (CSL). The selectively grown silicon layers may extend onto the device isolation layers 102 from the active regions 110 and may be connected to each other to form a silicon layer 134a for the common source line (CSL) (see FIG. 3). The silicon layer 134a may be grown to have a top surface higher than top surfaces of the device isolation layers. The height of the silicon layer 134a may be determined such that the common source line (CSL) has conductivity sufficient to serve its function as the common source line (CSL). For instance, a height of the silicon layer 134a according to example embodiments may be determined to be one third of a height of the gate structure 120.

A metal silicide layer 134b may be deposited on the silicon layer 134a to increase conductivity. The metal silicide layer 134b may be formed by depositing a metal layer on the semiconductor substrate 100, annealing the metal layer to form a metal silicide layer 134b at the boundary between the metal layer and the silicon layer 134a and then removing the remaining metal layer. The metal silicide layer 134b may be, for example, a tungsten silicide layer, a cobalt silicide layer or a nickel silicide layer. A wet etch may be performed using hydrogen fluoride acid. The silicon layer 134a and the metal silicide layer 134b may constitute a common source line (CSL).

Referring to FIGS. 5D and 5E, the spacer insulating layer 131 may be etched to form the sidewall spacer 133 on the sidewall of the gate structure 120. The etch process of the spacer insulating layer 131 may be anisotropic. An etch stop layer 141 may be formed on the gate structure 120, the sidewall spacer 133 and the common source line (CSL). An insulating interlayer 143 may be formed on the etch stop layer 141. The etch stop layer 141 and the insulating interlayer 143 may be formed of materials having different etch selectivity with respect to each other. The etch stop layer may be, for example, a silicon oxide or a silicon nitride. The insulating interlayer may be a silicon oxide layer (e.g., BPSG layer). The insulating interlayer 143 may be polished using a chemical mechanical polishing (CMP) process. A photoresist pattern (not shown) for forming a bit line contact hole 145 may be formed on the insulating interlayer 143. The photoresist pattern may include an opening (not shown) which corresponds to a region between a pair of adjacent string selection transistors (SST). The insulating interlayer 143 may be etched so that an etch stop layer 141 between a pair of adjacent string selection transistors (SST) is exposed. The etch stop layer 141 is etched so that an active region 110 between a pair of adjacent string selection transistors (SST) is exposed.

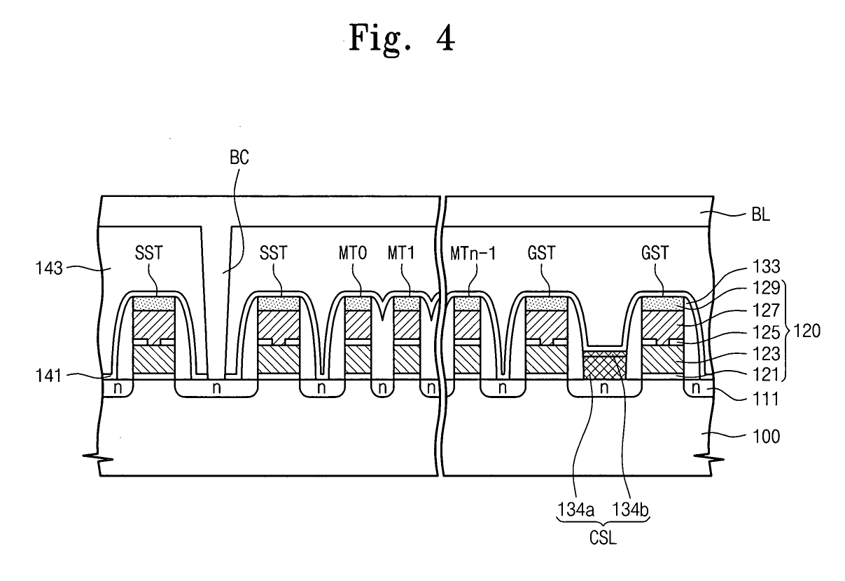

Referring to FIG. 4 again, a metal layer may be deposited on the insulating interlayer 143 and an exposed active region 110. The metal layer may be, for example, tungsten. The deposited metal layer may be polished and patterned to form a bit line contact (BC) and a bit line (BL).

In a nonvolatile memory device according to example embodiments, a separate lower insulation interlayer and/or a contact plug for the common source line (CSL) are not required. Accordingly, the height of the insulation interlayer may be reduced and the margin for a subsequent interconnection process may be increased, while the overall number of processing steps may be reduced.

The common source line (CSL) according to example embodiments may be formed using SEG. Thus, problems due to miss alignment of the photoresist pattern (PR) and/or over etch or under etch of the common source line (CSL) are reduced or prevented.

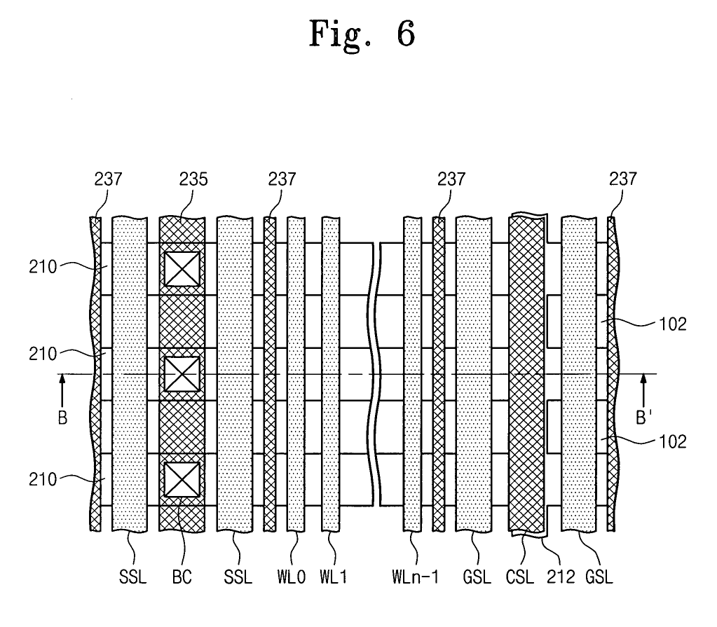

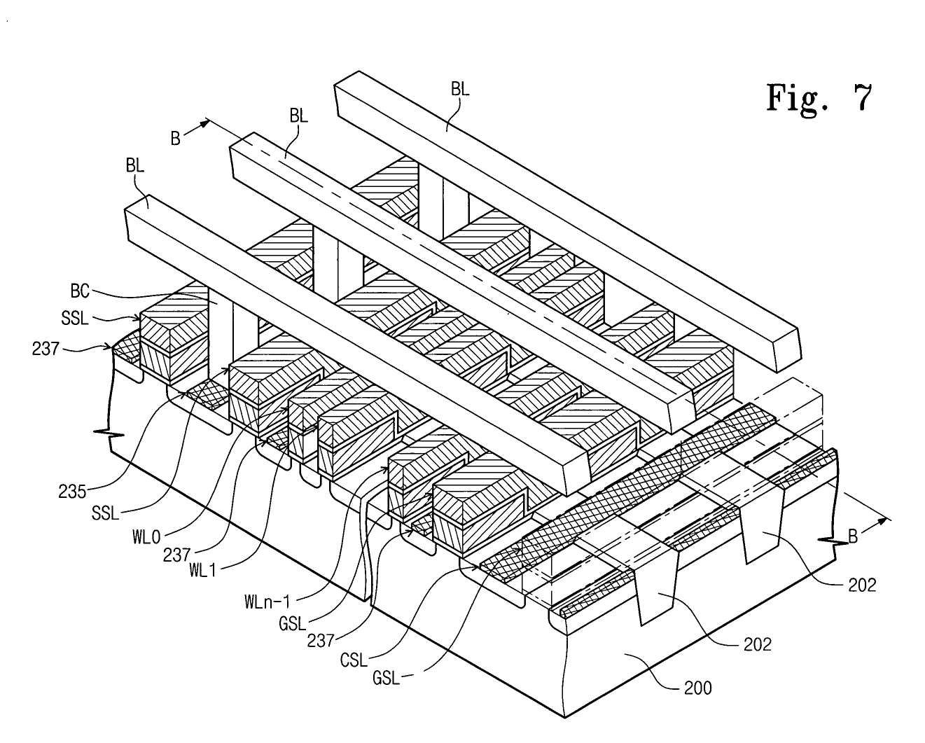

Example embodiments of a nonvolatile memory device will be described. Referring to FIGS. 6 through 8, active regions 210 in a semiconductor substrate 200 (e.g. silicon), may be formed to be parallel to each other by device isolation layers 202. Common source regions 212, on which common source lines (CSL) may be formed, may extend in a direction crossing the active regions 210 and may be connected to each other. For example, the active regions 210 may be connected to each other by the common source region 212. A plurality of transistors (SST, GST, MT0-MTn-1) may be formed on the active region 212. A plurality of memory cell transistors may be formed between a pair of adjacent ground selection transistors (GST) and a pair of adjacent string selection transistors (SST). A plurality of memory cell transistors (MT0-MTn-1) may form a string.

A string selection line (SSL) connected to the string selection transistor (SST) may extend in a direction crossing the active region 210. Word lines (WL0-WLn-1) connected to the memory cell transistors (MT0-MTn-1) may extend in a direction crossing the active region 210. A silicon layer 233a and a metal silicide layer 233b may be deposited on the common source region 212 and active regions 210, between a pair of adjacent ground selection transistors (GST). The silicon layer 233a and the metal silicide layer 233b may form a common source line (CSL). A silicon layer 235a and a metal silicide layer 235b may be deposited on an active region between a pair of adjacent string selection transistors (SST). A silicon layer 237a and a metal silicide layer 237b may deposited on an active region between the selection transistors (SST, GST) and the memory cell transistors adjacent to the selection transistors (SST, GST).

A nonvolatile memory device according to example embodiments may include silicon layer 235a and metal silicide layer 235b deposited on an active region between a pair of adjacent string selection transistors (SST). A bit line contact (BC) may be connected to the silicon layer 235a and/or the metal silicide layer 235b. Thus, a margin for reducing or preventing an over etch and an under etch of the bit line contact (BC) is increased due to the SEG grown silicon and/or silicide.

A NAND flash memory device according to example embodiments may include silicon layer 237a and metal silicide layer 237b deposited on an active region between selection transistors (SST, GST) and memory cell transistors (MT0-MTn-1) adjacent to selection transistors (SST, GST). Silicon layer 237a and metal silicide layer 237b may reduce or prevent program disturbances from being generated if high voltage is applied to selection lines (SSL, GSL). When high voltage is applied to the selection lines (SSL, GSL), a high electric field is formed between the selection transistors (SST, GST) and the memory cell transistors (MT0-MTn-1) adjacent to the selection transistors (SST, GST), which generates hot electrons. If hot electrons transfer to a string of the memory cell transistors (MT0-MTn-1), a program disturbance may occur due to hot electron injection. Silicon layer 237a and metal silicide layer 237b may be disposed between selection transistors (SST, GST) and memory cell transistors (MT0-MTn-1) adjacent to selection transistors (SST, GST) to reduce this electric field and prevent hot electron injection.

A bit line (BL) may be connected to silicon layer 235a and/or metal silicide layer 235b disposed between a pair of adjacent string selection transistors (SST) through bit line contact (BC). The bit line (BL) may extend onto active regions 210. Each of the transistors (SST, GST, MT0-MTn-1) may have a gate structure 220 which may include a tunnel insulating layer 221, a charge storage layer 223, a blocking insulating layer 225, a control gate layer 227 connected to the selection lines (SSL, GSL) or word lines (WL0-WLn-1), and a capping layer 229 on the control gate layer 227. The control gate layer 227 may include a polysilicon layer and a metal silicide layer on the polysilicon layer. A sidewall spacer 231 may be further provided onto the side surface of the gate structure 220. Charge storage layer 223 of the selection transistors (SST, GST) can be electrically connected to the control gate layer 227. The bit line (BL) and the transistors (SST, GST, MT0-MTn-1) are electrically disconnected from each other by an etch stop layer 241 and an insulating interlayer 243.

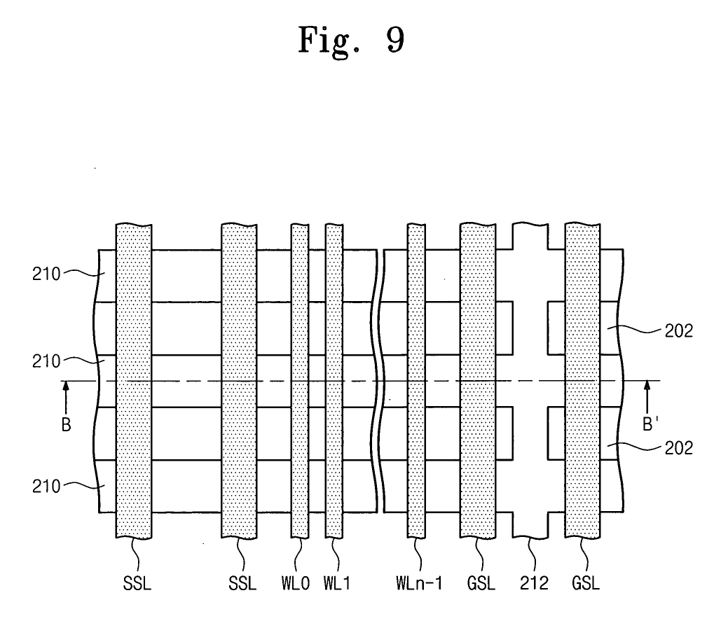

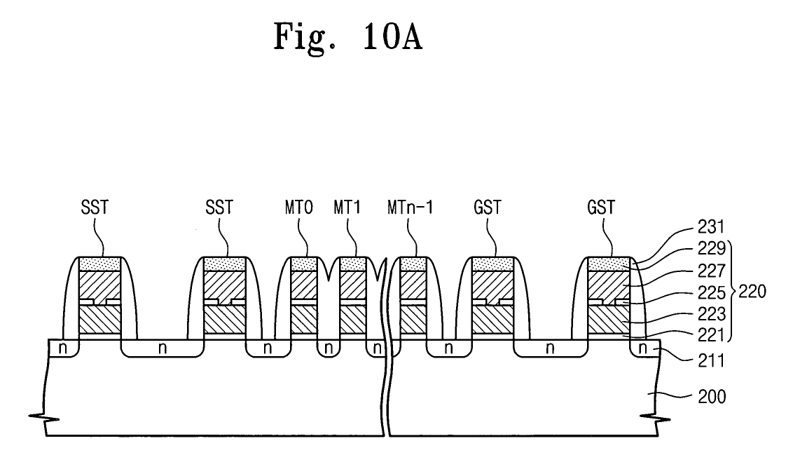

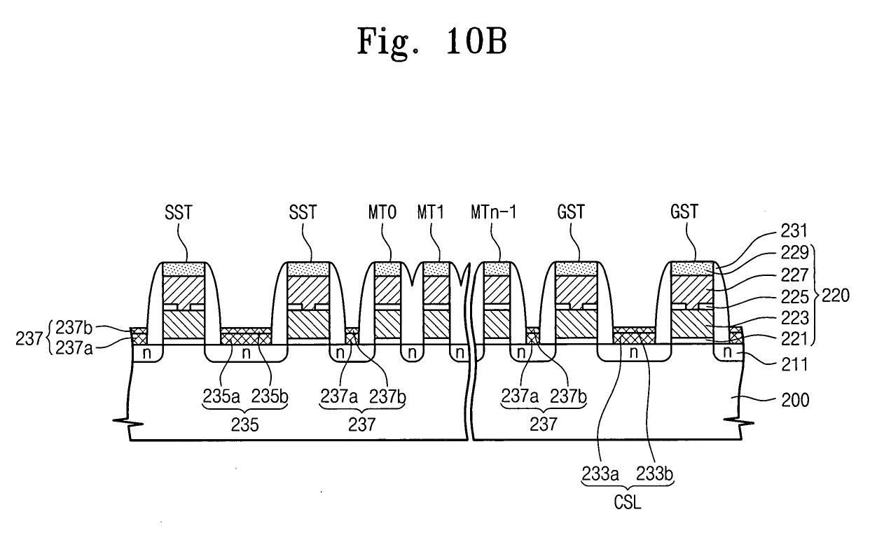

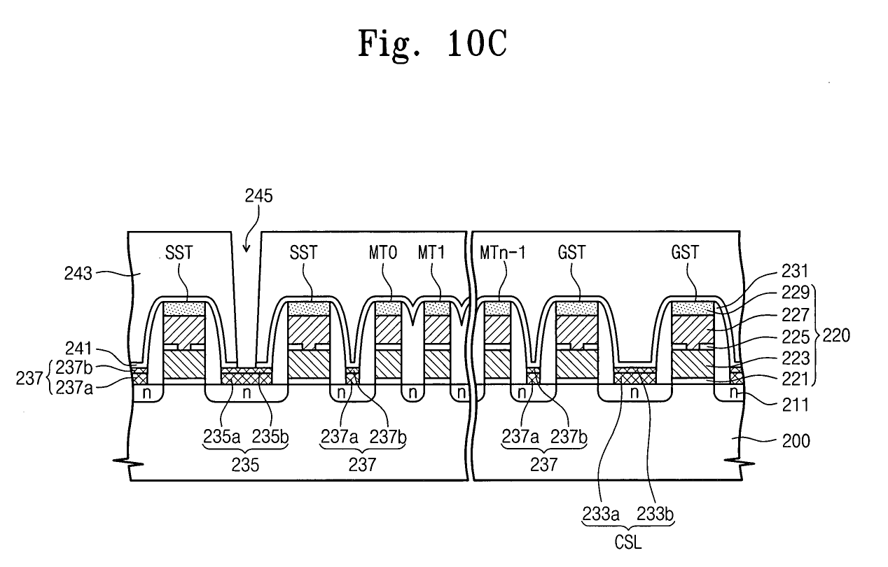

Referring to FIGS. 9 through 10C, a method of forming a nonvolatile memory device according to example embodiments will be described.

Referring to FIGS. 9 and 10A, a device isolation layer 202 may be formed in a semiconductor substrate 200. The device isolation layer 202 may define active regions 210 for transistors (SST, GST, MT0-MTn-1). A common source region 212 may be formed at a region where a common source line (CSL) may be formed. The common source region 212 may connect the active regions 210 and may extend in a direction crossing the active regions 210.

A gate structure 220 including a tunnel insulating layer 221, a charge storage layer 223, a blocking insulating layer 225, a control gate layer 227 and a capping layer 229 may be formed. A tunnel insulating layer 221 may be formed on the active regions 210. The tunnel insulating layer may, for example, include a silicon oxide layer. A charge storage layer 223 may be formed on the tunnel insulating layer 221. The charge storage layer 223 may be a floating gate, which may include polysilicon. The charge storage layer 223 may include a dot layer or a charge trap layer. The dot layer may include a conductor of a dot shape or an insulating layer including an insulator. The charge trap layer may be an insulating layer (e.g., a silicon nitride layer) including a site in which charges can be trapped. A blocking insulating layer 225 may be formed on the charge storage layer 223. The blocking insulating layer 223 may include oxide/nitride/oxide (ONO). A control gate layer 227 may be formed on the blocking insulating layer 225. The control gate layer 227 may include polysilicon. A metal silicide layer may be formed on the polysilicon layer. The metal silicide layer may, for example, be a tungsten silicide layer, a cobalt silicide layer or a nickel silicide layer. A portion of the blocking insulating layer 225 of selective transistors (SST, GST) may be etched to electrically connect the control gate layer 227 to the charge storage layer 223. A capping layer 229 may be formed on the control gate layer 227. The capping layer 227 may include a silicon nitride layer. The capping layer 229, the control gate layer 227, the blocking insulating layer 225, the charge storage layer 223 and the tunnel insulating layer 221 may be patterned in order.

Source/drain regions for transistors (SST, GST, MT0-MTn-1) may be formed in the active regions 210. The common source region 212 may be doped in the same manner as the source/drain regions of the adjacent ground selection transistor (GST). A sidewall spacer 231 may be formed on a side surface of the gate structure 220. The sidewall spacer 231 may be, for example, a silicon oxide layer, a silicon nitride layer or a combination of a silicon oxide layer and a silicon nitride layer. The spacer insulating layer 231 and the gate structure 220 may expose an active region between a pair of adjacent string selection transistors (SST), active regions between selection transistors (SST, GST) and memory cell transistors (MT0-MTn-1) adjacent to the selection transistors (SST, GST) and a top surface of the device isolation layer 202.

Referring to FIGS. 9 and 10B, a silicon layer may be grown from top surfaces of the exposed active regions. The silicon layer may be grown using SEG. A first silicon layer 233a may be grown from an active region between a pair of adjacent ground selection transistors (GST), and also the common source region 212. A second silicon layer 235a may be grown from an active region between a pair of adjacent string selection transistors (SST). A third silicon layer 237a may be grown from active regions between selection transistors (SST, GST) and memory cell transistors (MT0, MTn-1) most adjacent to the selection transistors (SST, GST). The first layers 233a may be grown so that they do not extend onto the device isolation layer 202 and are connected to each other. The second layers 235a may be grown so that the second layers 235a do not extend onto the device isolation layer 202 and are not connected to each other. The third layers 237a may be grown so that the third layers 237a do not extend onto the device isolation layer 202 and are not connected to each other. A first through third metal silicide layers 233b, 235b and 237b may be deposited on the first through third silicon layers 233a, 235a and 237a. The metal silicide layer may be, for example, a tungsten silicide layer, a cobalt silicide layer or a nickel silicide layer. The first silicon layer 233a and the first metal silicide layer 233b form a common source line (CSL).

Referring to FIG. 10C, an etch stop layer 241 is formed on the gate structure 220, the sidewall spacer 231 and the first through third metal silicide layers 233b, 235b and 237b. The etch stop layer 241 may be, for example, silicon oxynitride or silicon nitride. An insulating interlayer 243 is formed on the etch stop layer 241. The insulating interlayer 243 may be, for example, a silicon oxide layer (e.g., BPSG). The etch stop layer 241 and the insulating interlayer 243 may be formed of materials having different etch selectivity with respect to each other. The insulating interlayer 243 may be polished using a chemical mechanical polishing method. A photoresist pattern (not shown) for forming a bit line contact (BC) may be formed on the insulating interlayer 243. The photoresist pattern may include an opening (not shown) which corresponds to a region between a pair of adjacent string selection transistors (SST). The insulating interlayer 143 and the etch stop layer 241 may be etched between a pair of adjacent string selection transistors (SST) so that the second silicon layer 235a and/or the second metal silicide layer 235b may be exposed. As a result, a bit line contact hole 245 may be formed.

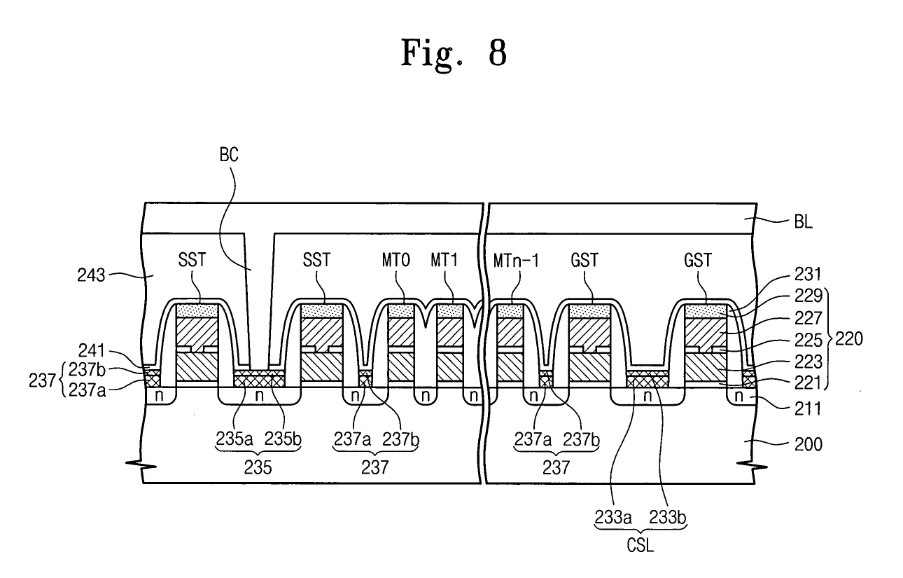

Referring to FIGS. 8 and 10C, a metal layer is deposited on the bit line contact hole 245 and the insulating interlayer 243. The metal layer may be, for example, tungsten. The deposited metal layer may be polished and patterned to form a bit line contact (BC) and a bit line (BL).

A common source line (CSL) of a nonvolatile memory device according to example embodiments may be formed using SEG. Problems such as a misalignment, an over etch or an under etch, which may occur during a formation of the common source line (CSL), are reduced or prevented. A separate lower insulation interlayer and/or a contact plug for the common source line (CSL) are not required. Accordingly, the height of the insulation interlayer may be reduced and the margin for a subsequent interconnection process may be increased, while the overall number of processing steps is reduced.

A nonvolatile memory device according to example embodiments may include the second silicon layer 235a and the second metal silicide layer 235b formed on an active region between a pair of adjacent string selection transistors (SST). The bit line (BL) may be connected to the second silicon layer 235a and/or the second metal silicide layer 235b. Thus, the margin for reducing or preventing an over etch or an under etch of the bit line contact (BC) may be increased.

A nonvolatile memory device according to example embodiments may include the third silicon layer 237a and the third metal silicide layer 237b disposed on active regions 210 between selection transistors (SST, GST) and memory cell transistors (MT0-MTn-1) adjacent to the selection transistors (SST, GST). The third silicon layer 237a and the third metal silicide layer 237b may reduce or prevent program disturbances from being generated if a high voltage is applied to the selection lines (SSL, GSL). When a high voltage is applied to the selection lines (SSL, GSL), a high electric field is be formed between the selection transistors (SST, GST) and the memory cell transistors (MT0-MTn-1) adjacent to the selection transistors (SST, GST), which generates hot electrons. If hot electrons transfer to a string of the memory cell transistors (MT0-MTn-1), a program disturbance may occur due to a hot electron injection. The third silicon layer 237a and the third metal silicide layer 237b are disposed between the selection transistors (SST, GST) and the memory cell transistors (MT0-MTn-1) adjacent to the selection transistors (SST, GST) to reduce this electric field and prevent hot electron injection.

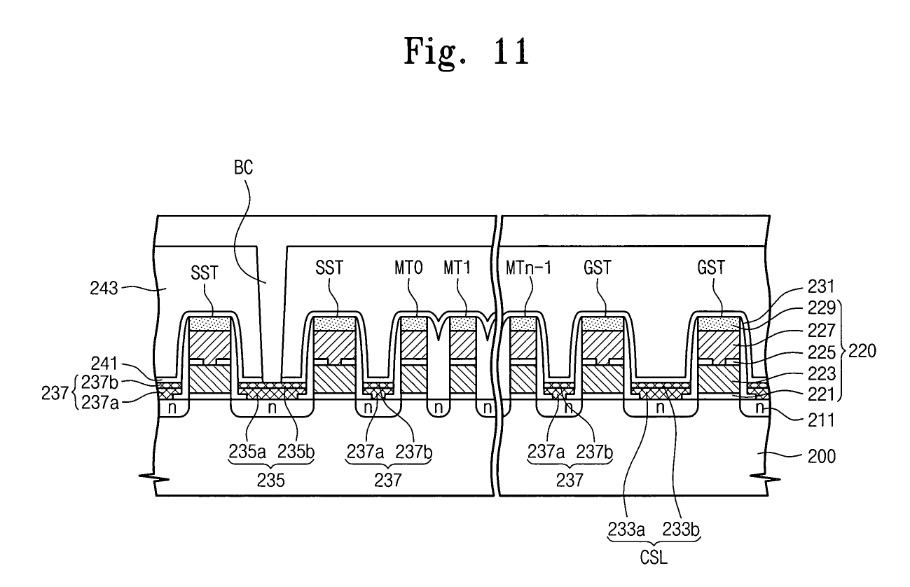

FIG. 11 is a cross sectional view illustrating example embodiments. Referring to FIG. 11, a sidewall spacer 231 may be formed to have an L-shape. The L-shaped sidewall spacer 231 may provide silicon layers grown using SEG with a larger area than a conventional sidewall spacer. Thus, the conductivity of silicon layers grown using SEG may be increased.

Example embodiments of a nonvolatile memory device will be described. Referring to FIGS. 6, 7 and 12, active regions 210 in a semiconductor substrate 200 (e.g. silicon), may be formed to be parallel to each other by a device isolation layer 202. Common source regions 212 on which common source lines (CSL) may be formed, may extend in a direction crossing the active regions 210 and may be connected to each other. A plurality of transistors (SST, GST, MT0-MTn-1) may be formed on the active regions 210. A plurality of memory cell transistors (MT0-MTn-1) may be formed between a pair of adjacent ground selection transistors (GST) and a pair of adjacent string selection transistors (SST). A plurality of memory cell transistors (MT0-MTn-1) may form a string.

A string selection line (SSL) connected to a string selection transistor (SST) may extend in a direction crossing the active regions 210. Word lines (WL0-WLn-1) connected to the memory cell transistors (MT0-MTn-1) may extend in a direction crossing the active regions 210. A first silicon layer 233a and a first metal silicide layer 233b may be stacked on a common source region 212 between a pair of adjacent ground selection transistors (GST). The first silicon layer 233a and the first metal silicide layer 233b may form a common source line (CSL). A second silicon layer 235a and a second metal silicide transistor 235b may be stacked on an active region between a pair of adjacent string selection transistors (SST). A third silicon layer 237a and a third metal silicide layer 237b may be stacked on active regions between selection transistors (SST, GST) and memory cell transistors (MT0-MTn-1) adjacent to the selection transistors (SST, GST).

A bit line (BL) may be connected to the second silicon layer 235a and/or the second metal silicide layer 235b between a pair of adjacent string selection transistors (SST) and the bit line (BL) may extend onto the active regions 210. The bit line (BL) and the transistors (SST, GST, MT0-MTn-1) may be disconnected from each other by an insulating interlayer 243. Each of the transistors (SST, GST, MT0-MTn-1) may have a gate structure 220 including a tunnel insulating layer 221, a charge storage layer 223, a blocking insulating layer 225 and a control gate layer 227 connected to selection lines (SSL, GSL) or word lines (WL0-WLn-1). The control gate layer 227 may include a polysilicon layer 227a and a fourth silicide layer 227b on the polysilicon layer 227a. The first through fourth metal silicide layers 233b, 235b and 237b may include a same material. A sidewall spacer 231 may be formed on a side surface of the gate structure 220. The charge storage layer 223 and the control gate layer 227 of the selection transistors (SST, GST) may be electrically connected to each other.

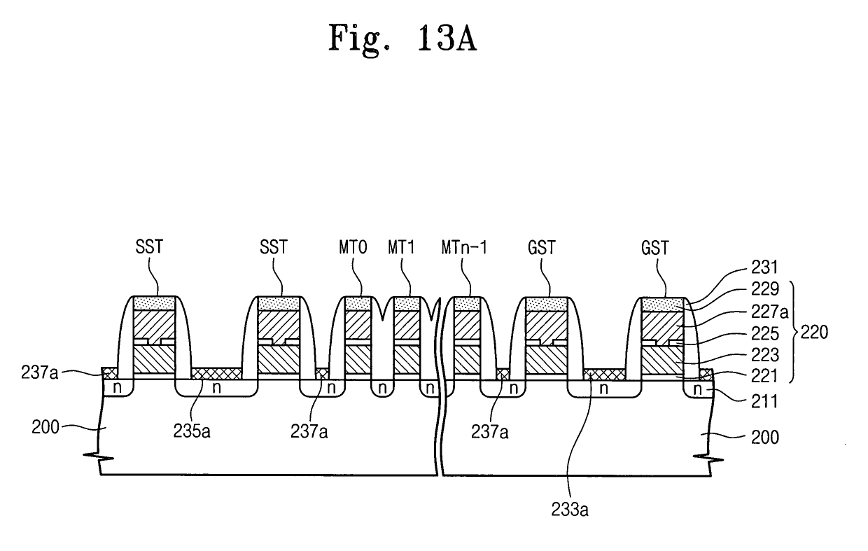

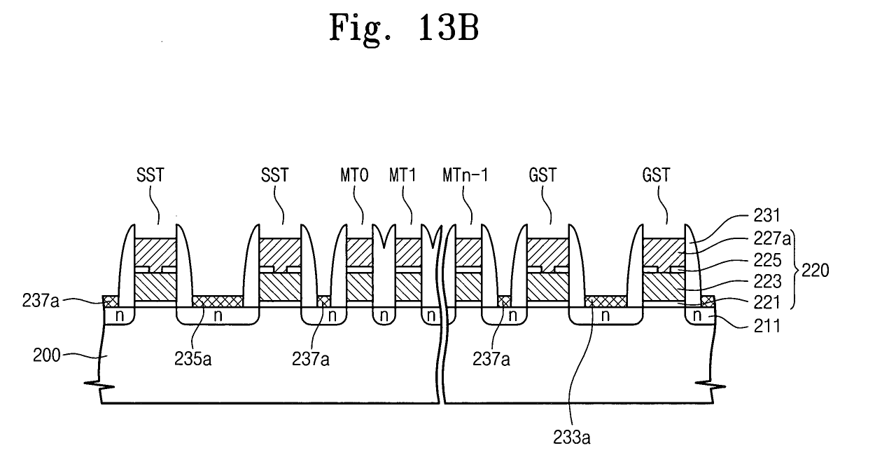

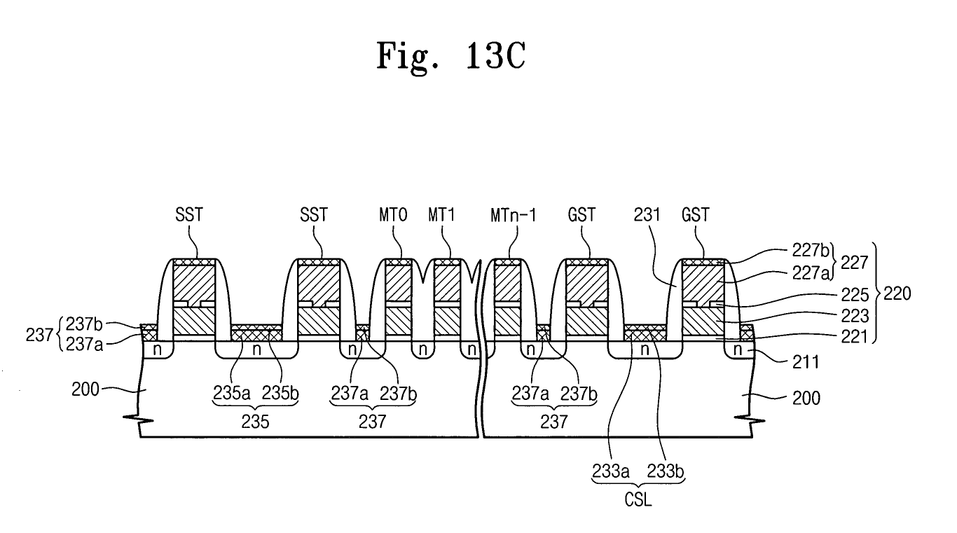

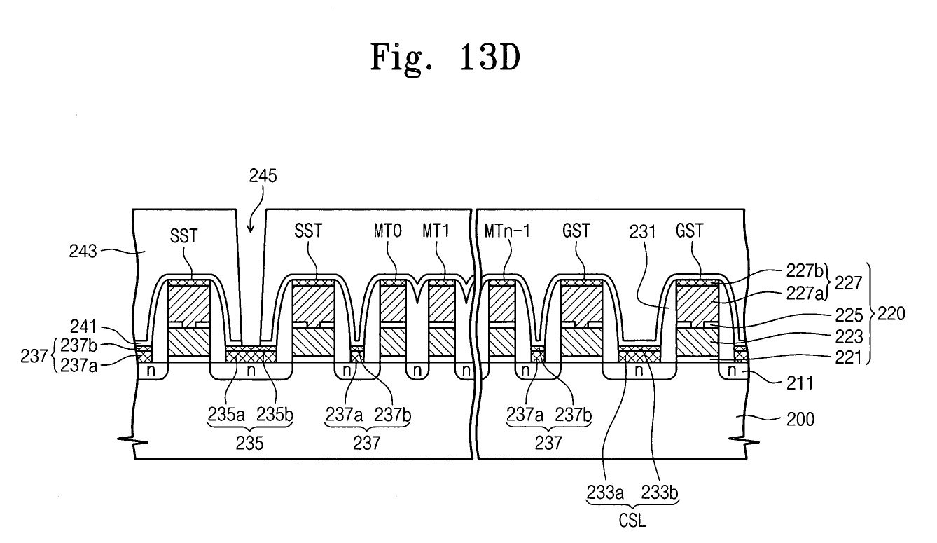

Referring to FIGS. 13A through 13D, a method of forming a common source line according to example embodiments will be described.

Referring to FIGS. 9 and 13A, a device isolation layer 202 may be formed in a semiconductor substrate 200. The device isolation layer 202 may define active regions 210 for transistors (SST, GST, MT0-MTn-1). A common source region 212 may be defined as a region on which a common source line (CSL) will be formed. The common source region 212 may extend in a direction crossing the active region 210 so as to connect active regions 210.

A gate structure 220 including a tunnel insulating layer 221, a charge storage layer 223, a blocking insulating layer 225, a polysilicon layer 227a and a capping layer 229 may be formed. A tunnel insulating layer 221 may be formed on the active regions 210. The tunnel insulating layer 221 may include, for example, a silicon oxide layer. A charge storage layer 223 may formed on the tunnel insulating layer 221. The charge storage layer 223 may be, for example, a floating gate including polysilicon. The charge storage layer 223 may include a dot layer or a charge trap layer. The dot layer may include a conductor of a dot shape or an insulating layer including an insulator. The charge trap layer may be an insulating layer (e.g., a silicon nitride layer) including a site in which charges can be trapped. A blocking insulating layer 225 may be formed on the charge storage layer 223. The blocking insulating layer may include, for example, ONO (oxide/nitride/oxide). A polysilicon layer 227a may be formed on the blocking insulating layer 225. A portion of a blocking insulating layer 225 of the selective transistors (SST, GST) may be etched so as to electrically connect a control gate layer 227 to the charge storage layer 223. A capping layer 229 may be formed on the polysilicon layer 227a. The capping layer 229 may include a silicon nitride layer. The capping layer 229, the polysilicon layer 227a, the blocking insulating layer 225, the charge storage layer 223 and the tunnel insulating layer 221 may be patterned in order.

Source/drain regions for transistors (SST, GST, MT0-MTn-1) may be formed in the active regions 210. The common source region 212 may be doped in the same manner as the source/drain regions of the adjacent ground selection transistor (GST).

A sidewall spacer 231 may be formed on the side surface of the gate structure 220. The sidewall spacer 231 may be a silicon oxide layer, a silicon nitride layer or a combination of a silicon oxide layer and a silicon nitride layer. The spacer insulating layer 231 may expose the common source region 212, an active region between a pair of adjacent string selection transistors (SST), active regions between selection transistors (SST, GST) and memory cell transistors (MT0-MTn-1) adjacent to the selection transistors (SST, GST), the capping layer 229 and a top surface of the device isolation layer 202.

A silicon layer may be grown using SEG from top surfaces of the exposed active regions. A first silicon layer 233a may be grown from an active region between a pair of adjacent string selection transistors (SST). A second silicon layer 235a may be grown from an active region between a pair of adjacent string selection transistors (SST). A third silicon layer 237a may be grown from active regions between selection transistors (SST, GST) and memory cell transistors (MT0, MTn-1) most adjacent to the selection transistors (SST, GST). The first layers 233a may be grown so that they do not extend onto the device isolation layer 202 and are connected to each other. The second layers 235a may be grown so that they do not extend onto the device isolation layer 202 and are not connected to each other. The third layers 237a may be grown so that they do not extend onto the device isolation layer 202 and are not connected to each other.

Referring to FIG. 13B, the capping layer 229 may be selectively removed, so that the polysilicon layer 227a may be exposed.

Referring to FIG. 13C, the first through fourth metal silicide layers 233b, 235b, 237b and 227b may be formed on the first through third silicon layers 233a, 235a and 237a, and the polysilicon layer 227a. The first through fourth metal silicide layers 233b, 235b, 237b and 227b may be formed of the same material. The metal silicide layer may be, for example, a tungsten silicide layer, a cobalt silicide layer or a nickel silicide layer. The first silicon layer 233a and the first metal silicide layer 233b may form a common source line (CSL). The polysilicon layer 227a and the fourth metal silicide layer 227b may form a control gate layer 227.

Referring to FIG. 13D, an etch stop layer 241 may be formed on a sidewall spacer 231 and the first through fourth metal silicide layers 233b, 235b, 237b and 227b. The etch stop layer 241 may, for example, be silicon oxynitride or silicon nitride. An insulating interlayer 243 may be formed on the etch stop layer 241. The etch stop layer 241 and the insulating interlayer 243 may be formed of material having a different etch selectivity with respect to each other. The insulating interlayer 243 may, for example, be silicon nitride. The insulating interlayer 243 may be polished using a chemical mechanical polishing method (CMP). A photoresist pattern (not shown) for forming a bit line contact (BC) may be formed on the insulating interlayer 243. The photoresist pattern may include an opening (not shown) which corresponds to a region between a pair of adjacent string selection transistors (SST). The insulating interlayer 143 may be etched so that an etch stop layer 141 between a pair of adjacent string selection transistors (SST) is exposed. The etch stop layer 241 may be etched so that the second silicon layer 235a and the second metal silicide layer 235b are exposed. As a result, a bit line contact hole 245 may be formed.

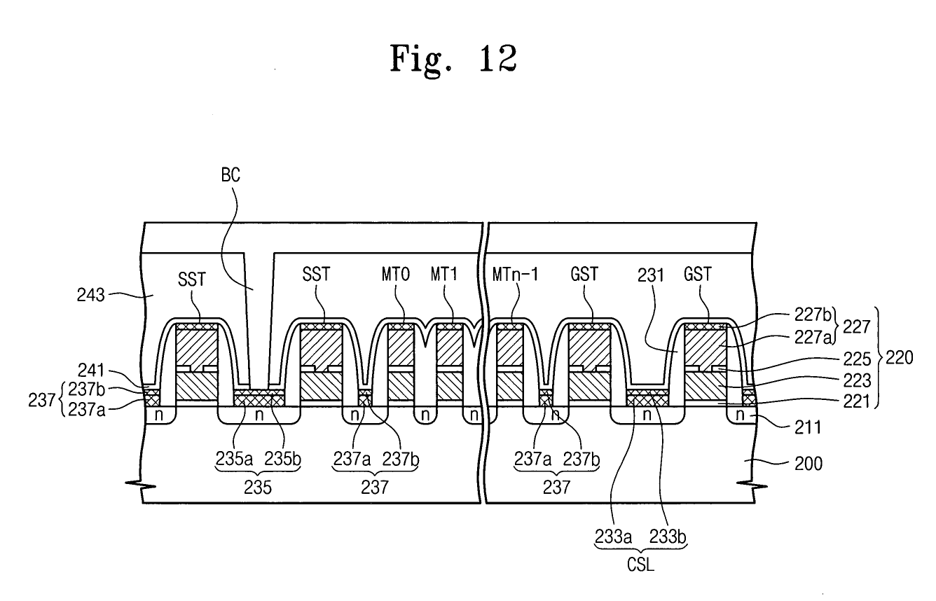

Referring to FIGS. 12 and 13D, a metal layer may be deposited on a bit line contact hole 245 and an insulating interlayer 243. The metal layer may be, for example, tungsten. The deposited metal layer may be polished and patterned to form a bit line contact (BC) and a bit line (BL).

A common source line (CSL) of a nonvolatile memory device according to example embodiments may be formed by growing a first silicon layer using SEG. Problems such as misalignment, an over etch or an under etch, that may occur during a formation of the common source line (CSL), may be reduced or prevented. A separate lower insulation interlayer and/or a contact plug for the common source line (CSL) may not be required. Accordingly, the height of the insulation interlayer may be reduced and the margin for a subsequent interconnection process may be increased, while the overall number of processing steps may be reduced.

A second silicon layer and a second metal silicide layer may be formed on an active region between a pair of adjacent string selection transistors (SST). A bit line contact (BC) may be connected to the second silicon layer and the second metal silicide layer. Thus, the margin for reducing or preventing an over etch or under etch of a bit line contact (BC) may be increased. A third silicon layer and a third metal silicide layer may be formed on an active region between selection transistors (SST, GST) and memory cell transistors (MT0, MTn-1) adjacent to the selection transistors (SST, GST). The third silicon layer and the third metal silicide layer may reduce or prevent program disturbances from being generated from a high voltage applied to the selection transistors (SST, GST). A fourth silicon layer and a fourth metal silicide layer may be formed on a control gate layer. Thus, conductivity of the control gate layer may be improved.

What is claimed is:

1. A method of forming a nonvolatile memory device, comprising:
forming a device isolation layer defining active regions in a semiconductor substrate;
forming a plurality of transistors on the active regions, the plurality of transistors comprising a pair of adjacent string selection transistors, a pair of adjacent ground selection transistors, and a plurality of memory cell transistors connected in series between the string selection transistors and ground selection transistors;
forming a common source line using selective epitaxial growth (SEG) between a pair of adjacent ground selection transistors so that the common source line has a top surface lower than a top surface of the pair of adjacent ground selection transistors.

2. The method of claim 1, wherein forming the common source line includes further forming a metal silicide layer on a silicon layer formed using SEG.

3. The method of claim 1, wherein the common source lines are epitaxially grown so that the common source lines extend onto the device isolation layer from the active regions and are connected to each other.

4. The method of claim 3, wherein forming the common source line comprises:
forming a spacer insulating layer on gate structures of the transistors:
forming a common source trench by etching the spacer insulating layer so as to selectively expose the active regions and the device isolation layer which are related to the common source line; and
forming a silicon layer on the active regions exposed by the common source trench using SEG.

5. The method of claim 4, further comprising:
anisotropically etching the spacer insulating layer to form a sidewall spacer on a sidewall of the gate structure.

6. The method of claim 5, further comprising:
forming an insulating interlayer on the semiconductor substrate including sidewall spacers;
forming contact holes exposing the active regions between a pair of adjacent string selection transistors; and
forming bit lines on the insulating interlayer, the bit lines being connected to the active regions between a pair of adjacent string selection transistors by contact plugs which fill the contact holes.

7. The method of claim 1, wherein the active regions extend in a specific direction and are formed to be parallel to each other, and wherein the device isolation layer additionally defines a common source region connecting the active regions by extending in a direction crossing the active regions so as to correspond to the common source line.

8. The method of claim 7, wherein the common source region is doped in the same manner as the source/drain regions of the adjacent ground selection transistor.

9. The method of claim 7, wherein forming the common source line comprises:
forming gate structures of the transistors on the semiconductor substrate;
forming sidewall spacers on sidewalls of the gate structures, the sidewall spacers exposing the active regions between a pair of adjacent ground selection transistors and a pair of adjacent string selection transistors; and
forming a silicon layer on the exposed active regions and the common source active region using SEG.

10. The method of claim 9, wherein the sidewall spacers additionally expose the active regions between the selection transistors and the memory cell transistors most adjacent to the selection transistors.

11. The method of claim 9, wherein the silicon layers are separated from each other on a top surface of the device isolation layer.

12. The method of claim 11, further comprising selectively forming metal silicide layers on the silicon layers formed using SEG.

13. The method of claim 11, wherein forming the gate structure comprises forming a tunnel oxide layer on the active region, a charge storage layer, a blocking insulating layer, a polysilicon layer and a capping layer, and wherein the method further comprises:
exposing the polysilicon layer by selectively removing the capping layer exposed by the sidewall spacers after an epitaxial growth of the silicon layers; and
selectively forming a metal silicide layer on the silicon layers formed using SEG and on the polysilicon layer.

14. The method of claim 13, wherein the capping layer has an etch selectivity with respect to the sidewall spacers, the silicon layer and the polysilicon layer.

15. A nonvolatile memory device, comprising:
a device isolation layer defining active regions in a semiconductor substrate;
a pair of adjacent string selection transistors on the active regions;
a pair of adjacent ground selection transistors on the active regions;
a plurality of memory cell transistors connected in series between the string selection transistors and the ground selection transistors on the active region; and
a common source line including a first silicon layer and a first metal silicide layer on the first silicon layer formed on the active region between the pair of adjacent ground selection transistors using selective epitaxial growth (SEG), wherein the common source line has a top surface lower than top surfaces of the transistors.

16. The nonvolatile memory device of claim 15, wherein the first silicon layers of the common source lines extend onto the device isolation layer and are connected to each other, the first silicon layers having an epitaxial structure on the device isolation layer.

17. The nonvolatile memory device of claim 15, wherein the active regions extend in a specific direction and are parallel to each other, the common source regions extending in a direction crossing the active regions to connect the active regions.

18. The nonvolatile memory device of claim 17, further comprising:
sidewall spacers disposed on sidewalls of the gate structures of the transistors, the sidewall spacers exposing active regions between the pair of adjacent ground selection transistors and between the pair of adjacent string selection transistors; and
a second silicon layer and a second metal silicide layer on the second silicon layer formed on the active region between the pair of adjacent string selection transistors and the common source region using SEG.

19. The nonvolatile memory device of claim 18, further comprising a third silicon layer and a third metal silicide on the third silicon layer formed on the active regions between the selection transistors and the memory cell transistors most adjacent to the selection transistors using SEG.

20. The nonvolatile memory device of claim 18, wherein the gate structure comprises a tunnel oxide layer on the active region, a charge storage layer, a blocking insulating layer, a polysilicon layer and a fourth metal silicide layer, and wherein the first and second metal silicide layers have the same metal as the fourth metal silicide layer.
